(19) United States
(12) Patent Application Publication
(10) Pub. No.: US 2011/0006210 A1
(43) Pub. Date: Jan. 13, 2011

(54) Method and Apparatus for Detecting Density and/or Thickness Variations in Materials Transparent or Partly Transparent to Infrared Radiation

(76) Inventors: Volker Märgner, Braunschweig (DE); Peter Meinlschmidt, Braunschweig (DE)

Correspondence Address: WHITHAM, CURTIS & CHRISTOFFERSON & COOK, P.C., 11491 SUNSET HILLS ROAD, SUITE 340, RESTON, VA, 20190, US

(21) Appl. No.: 12/921,649

(22) PCT Filed: Jan. 30, 2009
(86) PCT No.: PCT/EP09/00640

§ 371 Date: Sep. 9, 2010

(30) Foreign Application Priority Data
Mar. 27, 2008 (DE) 10 2008 016 195.0

(51) Int. Cl. H01L 31/00

(52) U.S. Cl. 250/330

(57) ABSTRACT

The invention relates to a method and an apparatus tor detecting density and/or thickness variations in materials transparent or partly transparent to infrared radiation, in which an examination object (1, 10) it arranged between an infrared source (3) and a thermographic camera (2), the examination object (1, 10) being irradiated by the inflated source (3) and the thermographic camera (2) arranged opposite the inflated source (3) detecting and evaluating the Infrared beams from the inflated source (3) passing through the examination object (1, 10).

The invention relates to a method and to an apparatus for detecting density and/or thickness differences in materials which are transparent or partly transparent to infrared radiation. The method and the apparatus are especially suitable for the examination of glass and thin, areal products such as screens, papers, parchments, plastics and the like. The method and the apparatus are likewise suitable for carrying out a rapid and reliable examination of banknotes and watermarked valuable and security papers and similar documents or, especially in the case of glass products, for ensuring the quality and safety of use.

Examination methods which take advantage of thermographic effects in order to detect inhomogeneities inside a product flow are known from the prior art. For example, DE 100 47 269 A1 describes a method for ascertaining the temperature distribution of bulk material coming from a drying process. The bulk material is separated over a drop distance and thermographically measured in a measurement region of the drop distance. It is the aim of the method in this case to detect thermal unevennesses due to agglomeration in an upstream drying method. The aim is especially to rule out risk of fire, which would be present if these agglomerations were to break up and hot regions were exposed to an increased supply of oxygen.

DE 6 95 03 663 T2 describes a method and a device for determining the authenticity of watermarked paper, in which method a paper region is heated, the temperature of the heated region is measured and subsequently the measurement is analyzed, with a series of temperature measurements being carried out in order to determine the thermal reaction of the paper as a function of time. This method is very time-consuming and necessarily requires the heating of the object under examination.

Thickness and density differences of thin, transparent or partly transparent materials are important not only in production, but also in cultural studies. Thickness and density differences, if they occur in locally adjacent regions, can generally be made visible simply in transmitted light methods. In partly transparent materials, such as for example milk glass or strongly blackened paper, light absorption can be so strong that a thickness or density difference in the transmitted light is no longer visible.

In the production of non-transparent glass bottles, for example flacons for cosmetics, what is referred to as “bird swings” can occur. This is a thin glass thread that extends from one wall of the bottle to another and cannot be seen from the outside. This glass thread can splinter during filling and thus contaminate the filling substance with glass splinters. Said glass splinters can under certain circumstances result in injury during use. It is therefore necessary to identify such production errors quickly and reliably. See-through glass or see-through containers and non-transparent containers into which an observer can see from above can be inspected visually by people or by an examination by way of video cameras, since the visible light spectrum can be used. However, glass products, in which the glass neither is transparent in the visible light nor the interior space of which can be viewed through an opening, such as for example bottles made of milk glass or bottles with a curved neck, cannot be inspected in the visible spectrum. Bottles which are designed in this manner cannot currently be checked for “bird swings” in a satisfactory manner, unless these production errors are such that they also entail defects on the glass exterior, which is not always the case.

Another problem occurs in the reliable recognition of watermarks in paper, for example in historic or even modern documents. Watermarks constitute deliberate thickness and possibly density differences in the paper and cultural scientists regard them as an important feature when determining the age and authenticity of historic documents. Watermarks in papers or similar thin objects can usually be identified by holding the document to be inspected against light and observing the transmitted light with the eyes. Watermarks can be identified as a brighter structure, that is to say as a structure which absorbs less light. This method of examination cannot be sufficient if the paper or the like contains text or drawings on one or both sides. Many text characters, lines or graphics in a dark ink can greatly limit the ability of the watermarks to be identified. In the case of dark ink applied over a surface area, this could result in watermarks being incapable of being made visible at all. In such cases, watermarks can only be rendered visible using X-rays which means that an X-ray machine must be transported to the object to be inspected, which can lead to safety-technology problems. The alternative of transporting documents to the X-ray-technological machines likewise encounters problems because the outlay incurred for ensuring safety and the special handling of the often valuable documents can be very costly and very time-consuming. The use of X-rays also requires a great outlay for the personal safety of the persons carrying out the examination.

It is therefore an object of the present invention to provide a method and an apparatus which can be used to render density and thickness differences visible in a simple manner, wherein the aim is especially for those objects to be able to be inspected that are only partly transparent or completely non-transparent against light of the visible wave spectrum.

According to the invention, this object is achieved by way of a method having the features of claim 1 and of an apparatus having the features of claim 11. Advantageous embodiments and developments of the invention are described in the dependent claims.

The method according to the invention for detecting density and/or thickness differences in materials which are transparent or partly transparent to infrared radiation, in which an object under examination is arranged between an infrared source and a thermography camera, provides that the object under examination is irradiated by the infrared source. The thermography camera arranged on that side of the object under examination that is opposite the infrared source detects the infrared radiation passing through the object under examination and evaluates it, with the result that it is possible to make visible thickness and density differences in plastics, glasses or papers, with text or pictures on them, screens and the like. The objects under examination are here not transparent or partly transparent to visible light, but can allow infrared radiation to pass through, with the result that the transmission radiation in the infrared range enables detection of many defects or structures in the object under examination which are not visible in visible light or are difficult to detect. Rather than detecting the rays absorbed by the object and then emitted, the thermography camera is used to detect the penetration radiation, with the result that this thermographic transmission inspection system can be used to immediately make visible and quickly record data relating to the density and/or thickness differences inside an object. The evaluation of the detected thermography data is performed using the methods of digital signal processing and pattern recognition and enables a quick comparison .of watermarks or else other incorporated patterns with existing patterns or recognition of concealed markings. It is likewise possible when applying the method in a production process to detect important parameters of a paper or of a film, for example in the case of a web sheet the web lengths, web spacings and web positions. Digital image processing and pattern recognition enable an adjustment of the detected image details and a simplified comparison with previously stored patterns. Use of the method together with a video camera additionally enables a common evaluation of brightness differences in incident light, for example in the case of text or graphics and the detected pattern with respect to density and/or thickness distribution, such as watermarks, for example.

One development of the invention provides for the thermography camera to store the transmitted infrared rays as an image rather than evaluating them immediately. The image evaluation can then take place after the storing in a computer.

A broadband infrared emitter that emits infrared rays in a longwave range of 0.8 um to 16 um can be used as an infrared source in order to enable examination of a variety of materials with various transmission properties using a single broadband infrared source. Alternatively, provision is made for a selective emitter to be used, which operates only in a specified wavelength range in order in this manner to transmit the infrared rays in a targeted manner through the object under examination. By way of example, diodes, lasers or flash lamps can be used as selective emitters.

In order to avoid damage by the infrared radiation to the object under examination, provision is made for the infrared emitter to be arranged spaced apart behind the object under examination, wherein provision may be made for the spacing from the object under examination to be of variable configuration, depending on which object under examination is being processed.

In order to be able to examine the entire object or the entire examination portion with respect to density differences or thickness differences, provision is made for the object under examination or the region to be examined of the object under examination to be irradiated homogeneously with infrared rays, so that inhomogeneities inside the image of the thermography camera cannot be traced back to inhomogeneities in the radiation source.

A filter, which allows through the infrared rays only in specific longwave ranges, for example in longwave ranges of 0.8-5 mm or of 8-16 μm, can be arranged between the thermography camera and the object under examination. In this case, the thermography camera is aligned in front of the object under examination such that the optical system that is being employed is used to image the object to be examined or the section of interest in an optimally sharp manner. Due to the selective wavelength ranges a sharper thermographic image can be obtained. Instead of, or in supplementation to, the arrangement of a filter, provision is made for a thermography camera to be used, which is sensitive to infrared rays in the longwave range of 0.8-5 μm or 8-16 μm in order in this manner to further increase the image sharpness of the thermography camera or to filter out any remaining, disturbing influences of the text or the drawing on top or the like.

The images recorded by the thermography camera can be transferred to a computer and are subjected to image processing in the computer in order, for example, to carry out an image improvement. To this end, image pre-processing methods can be used, which remove noise using linear and non-linear methods. In a further processing step, essential features of the image can be extracted and, if appropriate, automatic pattern recognition can be carried out. It is possible here, starting from available training data, to select a suitable method, wherein, if only a few training data items are present, a comparison is carried out of an unknown pattern for example using correlation in the image region or in the feature space. A feature space can, for example, be created by linear transformation of the image region into the spatial frequency space. If many training data items are present, methods of statistical pattern recognition are used, with which typical properties p are represented and can be demonstrated in unknown thermographic images.

The apparatus according to the invention for carrying out the method provides an infrared ray source which is assigned a holder for the object under examination. Furthermore, a thermography camera is provided, which is arranged on that side of the holder for the object under examination that is opposite the infrared source and which records and evaluates infrared radiation transmitted by an object under examination the infrared ray source. Backlighting with infrared rays also takes place, where the transmitted proportion of the infrared radiation is detected and evaluated.

The thermography camera can be equipped with at least one wavelength filter in order to increase the image sharpness or to avoid undesired surface effects. The infrared source can be in the form of a broadband infrared source, especially a heating plate or a heating mat, which is arranged behind the object to be examined or behind the object holder. Alternatively, the infrared source is in the form of a selective emitter, especially of a diode, flash lamp or laser, in order to emit only infrared rays of specific wavelength ranges to the object.

The holder for the object under examination can have a frame, which defines a free space between the object under examination and the infrared source in order in this manner to adjust the spacing between the object under examination and the infrared source. The holder for the object under examination can likewise be designed such that it can move relative to the infrared source in order in this manner to be able to build up an optimum spacing between the infrared ray source and the object under examination. This is used for protecting the object under examination against damage by the infrared radiation or by excessive intensity of the infrared radiation.

Exemplary embodiments of the invention will be explained in more detail below with reference to the attached figures, in which:

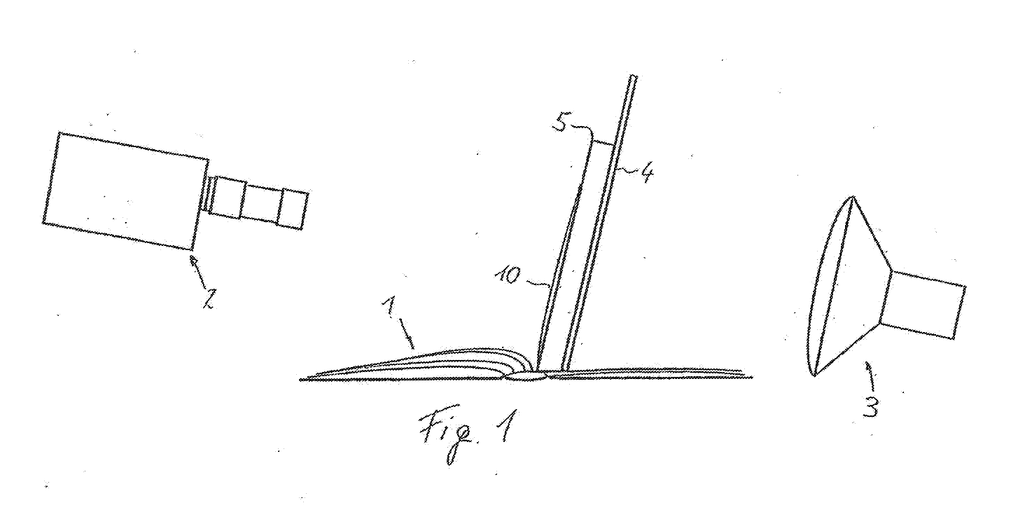

FIG. 1—shows a schematic design of an apparatus according to the present invention;

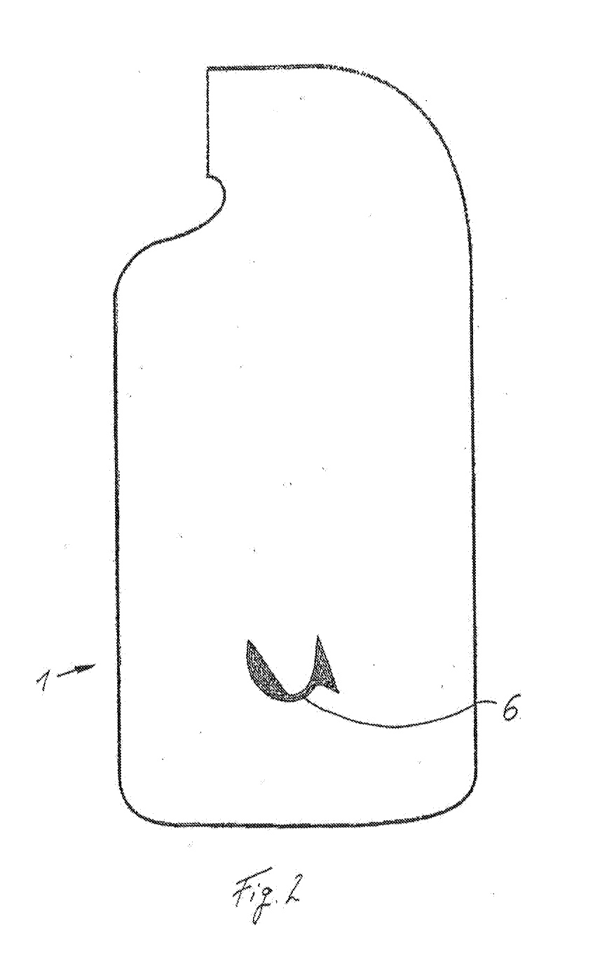

FIG. 2—shows an object under examination made of non-transparent glass; and

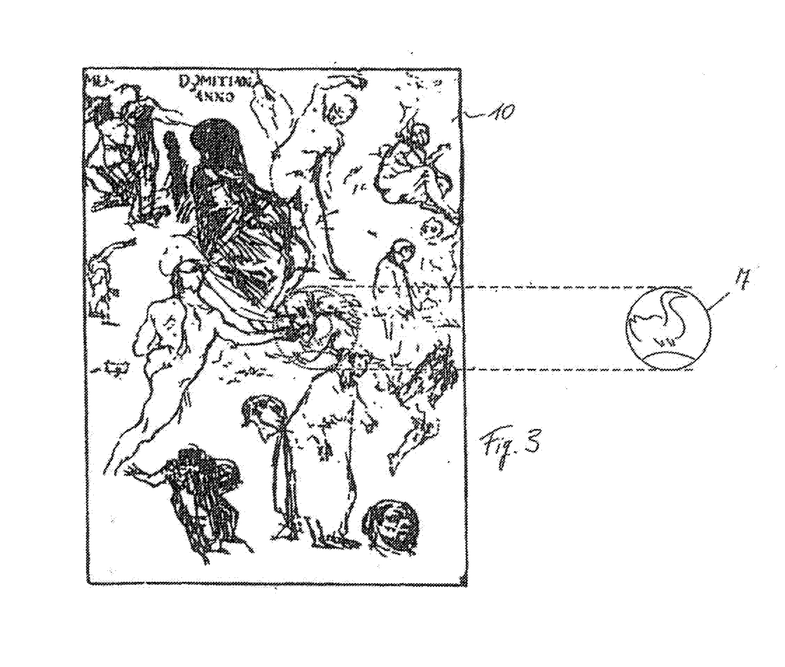

FIG. 3—an exemplary illustration of a printed object under examination.

FIG. 1 illustrates a schematic design of. an apparatus for detecting density and/or thickness differences, in which an object 1 under examination in the form of an open book is placed onto a support (not defined in any more detail). One sheet 10 of the object 1 under examination is upright and is located between, a thermography camera 2, Which is arranged in FIG. 1 to the left of the printed sheet 10 to be examined, and an infrared source 3. On that side of the object 10 to be examined that faces away from the thermography camera, the infrared source 3 in the form of a heating lamp is arranged. It is possible to use a variety of infrared sources 3 in place of a heading lamp, for example heating mats, diodes or laser emitters. The object 10 to be examined in the shape of a sheet bears against a metal plate 10, which is placed at an angle and acts as a holder. Arranged on the metal plate 4 is a spacer 5 for providing a sufficiently large spacing between the metal plate 4 and the object 10 under examination. The spacer 5 can likewise form a frame, with the result that only a specific region of the object 10 under examination is exposed to the infrared radiation from the heating lamp 4. If the metal plate 4 has a closed design, it is heated by the infrared emitter 3 and emits infrared radiation in the desired wavelength range in the direction, of the thermography camera 2. In the process, the infrared radiation penetrates the object 10 under examination and density or thickness differences in the object 10 under examination can be detected via the thermography camera 2, which can be equipped with suitable wavelength filters, since locations of different thickness or density inside the object 10 under examination have different transmission behaviors for infrared radiation.

If, rather than a continuous metal plate 4, only a frame with a spacer 5 is configured, the infrared rays from the infrared source 3 impinge directly on the object 10 under examination, and the infrared rays passing through the object 10 under examination are detected and evaluated by the thermography camera 2. The evaluation can also take place in a computer (hot illustrated), which is connected to the thermography camera 2. If the infrared source 3 used is a flash lamp, it is possible by single or multiple brief irradiation of the object 10 under examination with infrared rays for a very quick examination of the object 10 under examination to be carried out, with the result that as a result of the short-term irradiation a great number of objects 10 under examination can be examined within a short period of time. In particular for money notes, valuable papers, other documents with watermarks or the like and valuable pieces of art, it is possible to carry out an examination in a simple manner which is gentle on the material and to detect watermarks or the like inside the documents or objects.

It is also possible to examine three-dimensional objects rather than examining areal materials which are transparent or partly transparent to infrared radiation but are not transparent or only partly transparent for light in the visible wavelength range. FIG. 2 illustrates such a three-dimensional object 1 under examination in the form of a milk glass bottle. Due to the method of production, what is referred to as “bird swings” 6 may occur inside this bottle 1; these “bird swings” are glass threads which extend between the inside surfaces of a hollow glass body and can break during filling. The result is a risk of injuries due to sharp-edged glass particles during pouring and applying emulsions, for example. In order to be able to detect such bird swings 6, in particular those bird swings, into which it is not possible to see directly due to the shape of the object 1 or which are made of a non-transparent material, objects 1 under examination are likewise irradiated with infrared rays from an infrared source 3. Due to the variable transmissibility for infrared rays in the region of the bird swings 6 or in the region of the greater material thickness and the material accumulation between inside walls, correspondingly fewer infrared rays are transmitted by the body 3 under examination, which can be detected easily and quickly by the thermography camera 2. It is not necessary here either to heat the object 1 under examination, rather it suffices if infrared radiation is applied to the object to be examined only for a short period of time, since no emission of infrared rays on the part of the object 1 under examination takes place, but examination of the transmissivity.

FIG. 3 illustrates an example of an object 1 under examination in the form of a sheet of sketches from the Middle Ages. A watermark 7 in the drawing region of the sheet 10 cannot be detected or can be detected only with difficulty due to the colors. It is possible by way of transillumination using the apparatus according to FIG. 1 to clearly detect, due to the transmitted infrared radiation, a watermark 7 which can be used in order to determine the authenticity of the drawing or to date the piece of art.

Examination using short-time irradiation with infrared rays enables especially the recognition of watermarks on papers, which contain text or drawings in the region of the watermarks, since conventional transillumination with light in the visible wavelength range would not promise a lot of success here. In addition to the advantage of detecting density and thickness differences by means of transmission thermography, the lack of absorption of infrared radiation of many inks and colors also has a positive effect here. For example, the text or the drawing is usually not visible in an examination using infrared radiation, whereas the watermark as a thickness or density difference can be detected very well.

The density or thickness differences or watermarks 7 are available in the computer directly following the transillumination, with the result that, in addition to making the watermark visible for a subjective evaluation, an automatic, objective evaluation in the computer can take place on the screen, for example in order to compare the detected watermark 7 with another watermark from a database or in order to measure objective parameters in the present paper or object 10 under examination. Similar to a database of fingerprints, a database of watermarks, which contains other additional features, can be used to automatically categorize and, if appropriate, catalog: hitherto unknown sheets using the watermark 7 and the additional features.

1. A method for detecting density and/or thickness differences in materials which are transparent or partly transparent to infrared radiation, in which an object (1, 10) under examination is arranged between an infrared source (3) and a thermography camera (2), the object (1, 10) under examination is irradiated by the infrared source (3), and the thermography camera (2), which is arranged on that side of the object (1, 10) under examination that is opposite the infrared source (3), detects the infrared rays passing through the object (1, 10) under examination and evaluates them.

2. The method as claimed in claim 1, characterized in that the thermography camera (2) stores the transmitted infrared rays as an image.

3. The method as claimed in claim 1, characterized in that a broadband infrared emitter or a selective emitter is used as the infrared source (3).

4. The method as claimed in claim 1, characterized in that the infrared emitter (3) is arranged at a spacing behind the object (1, 10) under examination.

5. The method as claimed in claim 1, characterized in that the emission surface of the infrared emitter (3) is not greater than the projection surface of the object (1, 10) under examination.

6. The method as claimed in claim 1, characterized in that the object (1, 10) under examination is irradiated homogeneously.

7. The method as claimed in claim 1, characterized in that a filter, which allows through infrared rays in the longwave range of 0.8 to 5 μm or 8 to 16 μm, is arranged between the thermography camera (2) and the object (1, 10) under examination.

8. The method as claimed in claim 1, characterized in that a thermography camera (2) is used, which is sensitive to infrared rays in the longwave range of 0.6 to 5 μm or 8 to 16 μm.

9. The method as claimed in claim 1, characterized in that the images recorded by the thermography camera (2) are transferred to a computer and are subjected to image processing in the computer.

10. The method as claimed in claim 9, characterized in that the images are fed into an automatic pattern recognition.

11. An apparatus for carrying out the method as claimed in claim 1, comprising an infrared ray source (3) , a holder (4) for the object under examination, which is assigned to the infrared ray source (3), and a thermography camera (2), which is arranged on that side of the holder (4) for the object under examination that is opposite the infrared source (2) and which records and evaluates infrared radiation transmitted by an object (1, 10) under examination.

12. The apparatus as claimed in claim 11, characterized in that the thermography camera (2) is equipped with at least one wavelength filter.

13. The apparatus as claimed in claim 11, characterized in that the infrared source (3) is in the form of a broadband infrared source, especially a heating plate or heating mat.

14. The apparatus as claimed in claim 11, characterized in that the infrared source (3) is in the form of a selective emitter, especially of a diode, flash lamp or laser.

15. The apparatus as claimed in claim 11, characterized in that the holder (4) for the object under examination has a frame (5), which defines a free space between the object (1, 10) under examination and the infrared source (3).
